(19) United States
(12) Patent Application Publication
(10) Pub. No.: US 2026/0153797 A1
(43) Pub. Date: Jun. 4, 2026

(54) METHOD FOR MANUFACTURING LIQUID EJECTION HEAD, AND LIQUID EJECTION HEAD

(71) Applicant: CANON KABUSHIKI KAISHA, Tokyo (JP)

(72) Inventors: YOHEI HAMADE, Tokyo (JP); SATOSHI TSUTSUI, Kanagawa (JP); HARUKA YAMAJI, Tokyo (JP); ERIKA KOBATAKE, Kanagawa (JP)

(21) Appl. No.: 19/401,533

(22) Filed: Nov. 26, 2025

(30) Foreign Application Priority Data
Dec. 3, 2024 (JP) 2024-210496

(51) Int. Cl. G03F 7/00; B41J 2/16; G03F 7/029; G03F 7/032

(52) U.S. Cl. CPC G03F 7/0015; B41J 2/162; B41J 2/1631; G03F 7/029; G03F 7/032

(57) ABSTRACT

A method for manufacturing a liquid ejection head in which an ejection orifice-forming member that forms ejection orifices for ejecting a liquid and a flow path for the liquid that communicates with the ejection orifices is formed on a substrate, the manufacturing method including forming a mold for the flow path for the liquid on the substrate; coating a photosensitive resin composition for forming the ejection orifice-forming member onto the substrate, on which the mold has been formed, to form a cationically polymerizable resin layer; and exposing and developing the cationically polymerizable resin layer to form the ejection orifice-forming member, wherein the photosensitive resin composition includes at least one epoxy resin selected from the group consisting of an alicyclic epoxy resin and a glycidyl epoxy resin, and a cationic photopolymerization initiator having specific structure and molar absorption coefficient.

### BACKGROUND

### Field of the Technology

The present disclosure relates to a method for manufacturing a liquid ejection head, and a liquid ejection head.

### Description of the Related Art

Liquid ejection heads, such as inkjet recording heads used in inkjet recording (liquid jet recording) systems, typically include a plurality of ejection orifices, liquid flow paths, and energy-generating elements that are provided in portions of the flow paths to generate energy for ejecting a liquid.

In such liquid ejection heads, ink ejection performance is obviously significantly affected by the dimensions of the ejection orifices, as well as by the distance between the energy-generating elements and the ejection surface (orifices) containing the ejection orifices.

Japanese Patent Laid-Open No. H06-286149 discloses an ejection orifice formation method for forming ejection orifices by using a photosensitive resin by photolithography, as, i.e., a method for fabricating a liquid ejection head with high dimensional accuracy of components thereof and favorable reproducibility. The photosensitive resin, i.e., ejection orifice-forming components, is required to have high mechanical strength as a structural material, adhesiveness to a substrate containing energy generating elements, ink resistance, and resolution for forming fine patterns of ejection orifices.

Japanese Patent Laid-Open No. H06-286149 discloses that cationic polymerization cured products such as epoxy resins are suitable as photosensitive resins that meet these requirements. Japanese Patent Laid-Open No. H06-286149 uses SbF₆⁻, which demonstrates favorable polymerization and crosslinking performance that enable high adhesion, as the anion moiety of a cationic polymerization initiator (acid generator).

However, acid generators containing Sb, such as SbF6−, are highly toxic and designated as deleterious substances, and the use thereof is limited. The use of deleterious substances threatens people's health and global ecosystem, and hinders the realization of a sustainable society such as a decarbonized and recycling-oriented society. Therefore, the use of alternative initiators is required.

One alternative to acid generators containing SbF₆⁻ is a cationic polymerization initiator with B(C₆H₅)₆⁻ as anion moiety. However, cationic polymerization initiators with B(C₆H₅)₆⁻ as anion moiety generate a strong acid upon decomposition of the initiator, and while such initiators are effective in achieving high resin adhesion, such initiators also produce a large amount of hydrogen fluoride (HF) as a by-product, which may cause deterioration of base materials and equipment.

The present inventors recognized that, in particular, when an initiator containing B(C₆H₅)₆⁻ is used with an alicyclic epoxy resin or a glycidyl epoxy resin, film loss occurs due to a resin decomposition reaction at the time of high-temperature treatment during curing, making it difficult to obtain desired patterning dimensions. Furthermore, film loss may also reduce the adhesion of components.

The present disclosure provides a method for manufacturing a liquid ejection head in which high pattern precision is combined with high adhesiveness and which has favorable printing accuracy, and also provides such a liquid ejection head.

### SUMMARY

The present disclosure relates to a method for manufacturing a liquid ejection head in which an ejection orifice-forming member that forms ejection orifices for ejecting a liquid and a flow path for the liquid that communicates with the ejection orifices is formed on a substrate, the manufacturing method including:
forming a mold for the flow path for the liquid on the substrate;
coating a photosensitive resin composition for forming the ejection orifice-forming member onto the substrate, on which the mold has been formed, to form a cationically polymerizable resin layer; and
exposing and developing the cationically polymerizable resin layer to form the ejection orifice-forming member, wherein
the photosensitive resin composition includes at least one epoxy resin selected from the group consisting of an alicyclic epoxy resin and a glycidyl epoxy resin, and a cationic photopolymerization initiator (A),
the cationic photopolymerization initiator (A) is a salt having an anion represented by a following formula (1), and
a molar absorption coefficient of the cationic photopolymerization initiator (A) at a wavelength of 365 nm is at least 0.1 L/mol·cm:

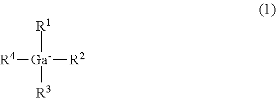

(In formula (1), R1 to R4 are each independently an alkyl group having 1 to 18 carbon atoms or Ar, provided that at least one of the R1 to R4 is Ar.

The Ar is an aryl group having 6 to 14 carbon atoms (not including the number of carbon atoms in following substituents), and some of hydrogen atoms in the aryl group may be substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR⁶, an acyl group represented by R⁷CO—, an acyloxy group represented by R⁸COO—, an alkylthio group or arylthio group represented by —SR⁹, an amino group represented by —NR¹⁰R¹¹, or a halogen atom. The R⁶ to R⁹ are each independently an alkyl group having 1 to 8 carbon atoms or an aryl group having 6 to 14 carbon atoms, and the R¹⁰ and R¹¹ are each independently a hydrogen atom, an alkyl group having 1 to 8 carbon atoms, or an aryl group having 6 to 14 carbon atoms).

Also, the present disclosure is directed to a liquid ejection head in which an ejection orifice-forming member that forms ejection orifices for ejecting a liquid and a flow path for the liquid that communicates with the ejection orifices is formed on a substrate, wherein
the ejection orifice-forming member is a cured product of a photosensitive resin composition;
the photosensitive resin composition includes at least one epoxy resin selected from the group consisting of an alicyclic epoxy resin and a glycidyl epoxy resin, and a cationic photopolymerization initiator (A),
the cationic photopolymerization initiator (A) is a salt having an anion represented by the above-mentioned formula (1), and
a molar absorption coefficient of the cationic photopolymerization initiator (A) at a wavelength of 365 nm is at least 0.1 L/mol·cm.

Features of the present disclosure will become apparent from the following description of embodiments with reference to the attached drawings. The following description of embodiments is described by way of examples.

### BRIEF DESCRIPTION OF THE DRAWINGS

FIG. 1 is a perspective view of an example of a liquid ejection head.

FIGS. 2A to 2G are cross-sectional views illustrating a method for manufacturing a liquid ejection head.

FIG. 3 is a schematic diagram of a cationically polymerizable resin layer formed in a laminated configuration.

### DESCRIPTION OF THE EMBODIMENTS

In the present disclosure, unless otherwise specified, the expressions “from XX to YY” or “XX to YY” representing a numerical range refer to a numerical range that includes both the lower and upper limits. When a numerical range is stated in stages, the upper and lower limits of each numerical range can be arbitrarily combined. Furthermore, in the present disclosure, a statement such as “at least one selected from the group consisting of XX, YY, and ZZ” means any of XX, YY, ZZ, a combination of XX and YY, a combination of XX and ZZ, a combination of YY and ZZ, or a combination of XX, YY, and ZZ. When XX is a group, multiple members may be selected from XX, and the same applies to YY and ZZ.

Preferred embodiments of the present disclosure are described hereinbelow. The method for manufacturing a liquid ejection head of the present disclosure is not limited to the following embodiments. Furthermore, in the following description, components having the same function are denoted by the same reference numerals in the drawings, and the description thereof may be omitted.

The present disclosure relates to a method for manufacturing a liquid ejection head in which an ejection orifice-forming member that forms ejection orifices for ejecting a liquid and a flow path for the liquid that communicates with the ejection orifices is formed on a substrate, the manufacturing method including the steps of:
forming a mold for the flow path for the liquid on the substrate;
coating a photosensitive resin composition for forming the ejection orifice-forming member onto the substrate on which the mold has been formed to form a cationically polymerizable resin layer; and
exposing and developing the cationically polymerizable resin layer to form the ejection orifice-forming member, wherein
the photosensitive resin composition includes at least one epoxy resin selected from the group consisting of an alicyclic epoxy resin and a glycidyl epoxy resin, and a cationic photopolymerization initiator (A),
the cationic photopolymerization initiator (A) is a salt having an anion represented by a following formula (1), and
a molar absorption coefficient of the cationic photopolymerization initiator (A) at a wavelength of 365 nm is 0.1 L/mol·cm or greater.

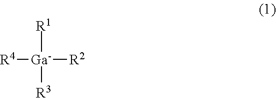

(In formula (1), R¹ to R⁴ are each independently an alkyl group having 1 to 18 carbon atoms or Ar, provided that at least one of R¹ to R⁴ is Ar.

The Ar is an aryl group having 6 to 14 carbon atoms (not including the number of carbon atoms in the following substituents), and some of the hydrogen atoms in the aryl group may be substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR⁶, an acyl group represented by R⁷CO—, an acyloxy group represented by R⁸COO—, an alkylthio group or arylthio group represented by —SR⁹, an amino group represented by —NR¹⁰R¹¹, or a halogen atom. R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms).

Each constituent component of the photosensitive resin composition is described hereinbelow.

### Epoxy Resin

The photosensitive resin composition contains at least one epoxy resin selected from the group consisting of an alicyclic epoxy resin and a glycidyl epoxy resin. This epoxy resin has good reactivity, high adhesiveness, and good mask reproducibility and print evaluation. The epoxy resin may contain both an alicyclic epoxy resin and a glycidyl epoxy resins.

Furthermore, for the water-repellent material described below, a solvent with a polar group, such as alcohol, is suitably selected to provide compatibility with the photosensitive resin composition. Therefore, an epoxy resin including an alicyclic epoxy resin and/or a glycidyl epoxy resin, which has a higher affinity for polar groups, can be suitably used.

Furthermore, from the viewpoint of patterning, it is preferable that the epoxy resin be solid at room temperature. The epoxy equivalent weight (g/eq.) of the epoxy resin is, for example, 1000 or less, preferably 900 or less, more preferably 500 or less, and even more preferably 250 or less. Where the epoxy equivalent weight (g/eq.) is set to 900 or less, the crosslink density does not decrease during the curing reaction, and a decrease in the glass transition temperature and adhesiveness of the cured product can be prevented. The epoxy equivalent weight (g/eq.) of the epoxy resin is, for example, 100 to 1000, preferably 120 to 900, more preferably 150 to 500, and even more preferably 150 to 250. The epoxy equivalent weight is a value measured in accordance with JIS K-7236.

Specific examples of the epoxy resin include at least one selected from the group consisting of methylenebis(3,4-epoxycyclohexane), propane-2,2-diyl-bis(3,4-epoxycyclohexane), 2,2-bis(3,4-epoxycyclohexyl) propane, dicyclopentadiene diepoxide, dioctyl epoxyhexahydrophthalate, di-2-ethylhexyl epoxyhexahydrophthalate, trimethylolpropane triglycidyl ether, and diglycidyl ether of polyethylene glycol.

Specific commercially available epoxy resins include Denacol EX-612 (manufactured by Nagase ChemteX Corporation), Denacol EX-614 (manufactured by Nagase ChemteX Corporation), Denacol EX-622 (manufactured by Nagase ChemteX Corporation), Denacol EX-861 (manufactured by Nagase ChemteX Corporation), Denacol EX-252 (manufactured by Nagase ChemteX Corporation), EHPE-3150 (manufactured by Daicel Chemical Industries, Ltd.), and Celloxide 3000 (manufactured by Daicel Chemical Industries, Ltd.).

### Cationic Photopolymerization Initiator

An ionic acid generator can be selected as the cationic photopolymerization initiator. The photosensitive resin composition contains a cationic photopolymerization initiator (A), which is a salt having an anion represented by formula (1). The molar absorption coefficient of the cationic photopolymerization initiator (A) at a wavelength of 365 nm is 0.1 L/mol·cm or more.

The photosensitive resin composition of the present disclosure contains a specific cationic photopolymerization initiator (A) for the abovementioned specific epoxy resin. The cationic photopolymerization initiator (A) is unlikely to generate HF during high-temperature treatment when curing the photosensitive resin composition, and is believed to be capable of suppressing film loss due to a resin decomposition reaction. As a result, it is believed possible to provide a liquid ejection head in which high pattern precision is combined with high adhesiveness and which has good printing accuracy.

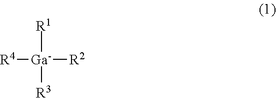

In formula (1), R¹ to R⁴ are each independently an alkyl group having 1 to 18 carbon atoms or Ar, provided that at least one of R¹ to R⁴ is Ar.

The Ar is an aryl group having 6 to 14 carbon atoms (not including the number of carbon atoms in the following substituents), and some of the hydrogen atoms in the aryl group may be substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR⁶, an acyl group represented by R⁷CO—, an acyloxy group represented by R⁸COO—, an alkylthio group or arylthio group represented by —SR⁹, an amino group represented by —NR¹⁰R¹¹, or a halogen atom. R⁶ to R⁹ are each independently an alkyl group having 1 to 8 carbon atoms or an aryl group having 6 to 14 carbon atoms, and R¹⁰ and R¹¹ are each independently a hydrogen atom, an alkyl group having 1 to 8 carbon atoms, or an aryl group having 6 to 14 carbon atoms.

It is preferable that R¹ to R⁴ be all Ar. Ar is an aryl group having 6 to 14 carbon atoms (preferably 6 to 10, more preferably 6, not including the carbon atoms of the following substituents), and some of the hydrogen atoms in the aryl group are substituted with an alkyl group having 1 to 8 carbon atoms (preferably 1 to 3, more preferably 1) substituted with a halogen atom, or with a halogen atom. It is preferable that 50% to 100% of the hydrogen atoms in the aryl group be substituted with a halogen atom. The halogen atom is preferably F.

Specific examples of the aryl groups having 6 to 14 carbon atoms (not including the carbon atoms of the following substituents) in R¹ to R⁴ in formula (1) include monocyclic aryl groups (e.g., phenyl), condensed polycyclic aryl groups (e.g., naphthyl, anthracenyl, phenanthrenyl, anthraquinonyl, fluorenyl, and naphthoquinonyl), aromatic heterocyclic hydrocarbon groups (e.g., monocyclic heterocycles such as thienyl, furanyl, pyranyl, pyrrolyl, oxazolyl, thiazolyl, pyridyl, pyrimidyl, and pyrazinyl, and condensed polycyclic heterocycles such as indolyl, benzofuranyl, isobenzofuranyl, benzothienyl, isobenzothienyl, quinolyl, isoquinolyl, quinoxalinyl, quinazolinyl, carbazolyl, acridinyl, phenothiazinyl, phenazinyl, xanthenyl, thianthrenyl, phenoxazinyl, phenoxathiinyl, chromanyl, isochromanyl, coumarinyl, dibenzothienyl, xanthenyl, thioxanthenyl, and dibenzofuranyl).

In addition to the above, the aryl group may have some of hydrogen atoms substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR6, an acyl group represented by R7CO—, an acyloxy group represented by R8COO—, an alkylthio group or arylthio group represented by —SR9, an amino group represented by —NR10R11, or a halogen atom.

From the viewpoint of catalytic activity in cationic polymerization reactions, these substituents are preferably an alkyl group having 1 to 8 carbon atoms substituted with a halogen atom, a halogen atom, a nitro group, or a cyano group, and more preferably an alkyl group having 1 to 8 carbon atoms substituted with a fluorine atom or a fluorine atom. Tetrakis(pentafluorophenyl)gallate is particularly suitable as the anion.

The cationic photopolymerization initiator (A) is, for example, a salt having a cation and an anion represented by formula (1). An onium-based cation with high absorption can be selected as the cation. That is, the cation of the cationic photopolymerization initiator (A) is preferably an onium-based cation. The onium-based cation is preferably at least one selected from the group consisting of onium ions such as oxonium-, ammonium-, phosphonium-, sulfonium-, and iodonium-based ions. Of these, sulfonium-based cations are preferred. Sulfonium ions excel in cationic polymerization performance and crosslinking reaction performance.

Sulfonium-based cations include, for example, at least one selected from the group consisting of triarylsulfonium compounds such as triphenylsulfonium, tri-p-tolylsulfonium, tri-o-tolylsulfonium, tris(4-methoxyphenyl)sulfonium, 1-naphthyldiphenylsulfonium, 2-naphthyldiphenylsulfonium, tris(4-fluorophenyl)sulfonium, tri-1-naphthylsulfonium, tri-2-naphthylsulfonium, tris(4-hydroxyphenyl)sulfonium, 4-(phenylthio)phenyldiphenylsulfonium, 4-(p-tolylthio)phenyldi-p-tolylsulfonium, 4-(4-methoxyphenylthio)phenylbis(4-methoxyphenyl)sulfonium, 4-(phenylthio)phenylbis(4-fluorophenyl)sulfonium, 4-(phenylthio)phenylbis(4-methoxyphenyl)sulfonium, 4-(phenylthio)phenyldi-p-tolylsulfonium, [4-(4-biphenylylthio)phenyl]-4-biphenylylphenylsulfonium, [4-(2-thioxomethylthio)phenyl]diphenylsulfonium, bis[4-(diphenylsulfonium)phenyl]sulfide, bis[4-{bis[4-(2-hydroxyethoxy)phenyl]sulfonio}phenyl]sulfide, bis{4-[bis(4-fluorophenyl)sulfonio]phenyl}sulfide, bis{4-[bis(4-methylphenyl)sulfonio]phenyl}sulfide, bis{4-[bis(4-methoxyphenyl)sulfonio]phenyl}sulfide, 4-(4-benzoyl-2-chlorophenylthio)phenylbis(4-fluorophenyl)sulfonium, 4-(4-benzoyl-2-chlorophenylthio)phenyldiphenylsulfonium, 4-(4-benzoylphenylthio)phenylbis(4-fluorophenyl)sulfonium, 4-(4-benzoylphenylthio)phenyldiphenylsulfonium, 7-isopropyl-9-oxo-10-thia-9,10-dihydroanthracen-2-yldi-p-tolylsulfonium, 7-isopropyl-9-oxo-10-thia-9,10-dihydroanthracen-2-yldiphenylsulfonium, 2-[(di-p-tolyl)sulfonio]thioxanthone, 2-[(diphenyl)sulfonio]thioxanthone, 4-(9-oxo-9H-thioxanthen-2-yl)thiophenyl-9-oxo-9H-thioxanthen-2-ylphenylsulfonium, 4-[4-(4-tert-butylbenzoyl)phenylthio]phenyldi-p-tolylsulfonium, 4-[4-(4-tert-butylbenzoyl)phenylthio]phenyldiphenylsulfonium, 4-[4-(benzoylphenylthio)]phenyldi-p-tolylsulfonium, 4-[4-(benzoylphenylthio)]phenyldiphenylsulfonium, 5-(4-methoxyphenyl)thiaanthrenium, 5-phenylthiaanthrenium, 5-tolylthiaanthrenium, 5-(4-ethoxyphenyl)thiaanthrenium, 5-(2,4,6-trimethylphenyl)thiaanthrenium, and 2-[(phenyl)sulfinyl]-9,9-dimethylfluorene; diarylsulfonium compounds such as diphenylphenacylsulfonium, diphenyl-4-nitrophenacylsulfonium, diphenylbenzylsulfonium, and diphenylmethylsulfonium; monoarylsulfonium compounds such as phenylmethylbenzylsulfonium, 4-hydroxyphenylmethylbenzylsulfonium, 4-methoxyphenylmethylbenzylsulfonium, 4-acetocarbonyloxyphenylmethylbenzylsulfonium, 4-hydroxyphenyl-methyl-1-naphthylmethylsulfonium, 4-hydroxyphenyl(2-naphthylmethyl)methylsulfonium, 2-naphthylmethylbenzylsulfonium, 2-naphthylmethyl (1-ethoxycarbonyl)ethylsulfonium, phenylmethylphenacylsulfonium, 4-hydroxyphenylmethylphenacylsulfonium, 4-methoxyphenylmethylphenacylsulfonium, 4-acetocarbonyloxyphenylmethylphenacylsulfonium, 2-naphthylmethylphenacylsulfonium, 2-naphthyloctadecylphenacylsulfonium, and 9-anthracenylmethylphenacylsulfonium; and trialkylsulfonium compounds such as dimethylphenylsulfonium, phenacyltetrahydrothiophenium, dimethylbenzylsulfonium, benzyltetrahydrothiophenium, and octadecylmethylphenacylsulfonium.

At least one selected from the group consisting of 4-hydroxyphenyl-methyl-1-naphthylmethylsulfonium, 4-hydroxyphenyl-methyl-benzylsulfonium, 4-hydroxyphenyl-methyl-4-nitrobenzylsulfonium, 4-hydroxyphenyldimethylsulfonium, 4-acetoxyphenyldimethylsulfonium, diphenyl[4-(phenylthio)phenyl]sulfonium, [4-(4-biphenylylthio)phenyl]-4-biphenylylphenylsulfonium, 2-[(di-p-tolyl)sulfonio]thioxanthone, 2-[(diphenyl)sulfonio]thioxanthone, triphenylsulfonium, and 2-[(phenyl)sulfinyl]-9,9-dimethylfluorene can be suitably used as the cation.

More preferably, the cationic moiety is at least one selected from the group consisting of 4-hydroxyphenyl-methyl-1-naphthylmethylsulfonium, [4-(4-biphenylylthio)phenyl]-4-biphenylylphenylsulfonium, 2-[(di-p-tolyl)sulfonio]thioxanthone, 2-[(diphenyl)sulfonio]thioxanthone, triphenylsulfonium, and 2-[(phenyl)sulfinyl]-9,9-dimethylfluorene.

The molar absorption coefficient of the cationic photopolymerization initiator (A) at a wavelength of 365 nm is 0.1 L/mol·cm or greater. A molar absorption coefficient of 0.1 L/mol·cm or greater prevents a decrease in crosslink density during the curing reaction and can prevent a decrease in the glass transition temperature and adhesiveness of the cured product.

The molar absorption coefficient of the cationic photopolymerization initiator (A) is preferably 0.1 L/mol·cm to 7.0 L/mol·cm, and more preferably 0.3 L/mol·cm to 5.0 L/mol·cm. The molar absorption coefficient of the gallate-based photoacid generator can be controlled, for example, by the structure of the cation.

The molar absorption coefficient of a compound such as the cationic photopolymerization initiator (A) is measured by the following method.

The target compound is dissolved in a solvent that has no absorption at a wavelength of 365 nm, such as acetonitrile, to form a solution. The solution is then placed in a quartz cell and the absorbance at a wavelength of 365 nm is measured using a UV-Visible-NIR Spectrophotometer (manufactured by JASCO Corporation). The molar absorption coefficient can be calculated from the obtained absorbance using the following formula:

$$Molar absorption coefficient = absorbance / molar concentration of compound / optical path of cell .$$

Furthermore, the amount of cationic photopolymerization initiator added is not particularly limited and can be freely adjusted to achieve the target sensitivity. The content of the cationic photopolymerization initiator (A) in the photosensitive resin composition is, for example, 0.05 parts by mass to 20 parts by mass, preferably 0.1 parts by mass to 10 parts by mass, more preferably 0.5 parts by mass to 10 parts by mass, even more preferably 1 part by mass to 5 parts by mass, and still more preferably 2 parts by mass to 5 parts by mass, per 100 parts by mass of the epoxy resin.

The photosensitive resin composition may contain a solvent such as xylene. The amount of solvent is, for example, 10 parts by mass to 200 parts by mass, or 20 parts by mass to 100 parts by mass, per 100 parts by mass of epoxy resin.

Furthermore, the photosensitive resin composition preferably contains a solvent that improves the distribution of the cationic photopolymerization initiator (A) within the photosensitive resin composition. Ester solvents can be suitably used as solvents that easily dissolve the cationic photopolymerization initiator (A). In other words, the photosensitive resin composition preferably contains an ester solvent.

Furthermore, an ester solvent with a high boiling point can be suitably used to prevent material aggregation due to rapid solvent evaporation in the heating step during coating film formation. An ester solvent with a boiling point of, for example, 75° C. or higher, or 100° C. or higher, can be suitably used. The boiling point of the ester solvent is preferably 75° C. to 300° C., or 100° C. to 250° C. Specific examples of the ester solvent include at least one selected from the group consisting of propylene glycol monomethyl ether acetate, propylene carbonate, ethyl acetate, isobutyl acetate, etc. The ester solvent is more preferably at least one selected from the group consisting of propylene carbonate and ethyl acetate.

Two or more solvents can be used. Xylene and an ester solvent may be used in combination. From the viewpoint of solubility, the photosensitive resin composition contains, for example, 0.1 parts by mass to 25 parts by mass, preferably 0.1 parts by mass to 10 parts by mass, and more preferably 1 part by mass to 7 parts by mass of the ester solvent per 100 parts by mass of the epoxy resin. Where the content is 0.1 parts by mass or more, the solubility of the photoinitiator is improved, resulting in a uniform coating film surface obtained with the photosensitive resin solution and making it easier to form a fine pattern. Furthermore, a content of 10 parts by mass or less results in no residual solvent remaining after baking and makes it easier to form a fine pattern.

Furthermore, in addition to the cationic photopolymerization initiator (A), the photosensitive resin composition preferably contains a cationic photopolymerization initiator (B) that is different from the cationic photopolymerization initiator (A) and has a quencher function. This allows for the capture of acid generated by leakage light during exposure and makes it possible to expect further improvement in pattern accuracy.

The cationic photopolymerization initiator (B) preferably has an anion with a weaker acid strength than the cationic photopolymerization initiator (A). That is, the photosensitive resin composition preferably further contains a cationic photopolymerization initiator (B) that is different from the cationic photopolymerization initiator (A) and has a lower acid strength than the cationic photopolymerization initiator (A). Examples of cationic photopolymerization initiators (B) include initiators with a sulfonic acid or hexafluorophosphoric acid structure.

Furthermore, since the quencher effect is determined by the anionic structure, the structure of the cation moiety is not particularly limited. A specific commercially available photoinitiator is TPS-1000 (manufactured by Midori Chemical Co., Ltd.). Furthermore, the content of the cationic photopolymerization initiator (B) in the photosensitive resin composition is preferably 0.01 times to 0.5 times, and more preferably 0.01 times to 0.05 times, the content of the cationic photopolymerization initiator (A) by mass.

Furthermore, for the purpose of accelerating curing after ejection orifice formation, the photosensitive resin composition preferably further contains a cationic thermal polymerization initiator. One method for accelerating curing of the ejection orifice-forming member is to increase the amount of cationic photopolymerization initiator, but in this case, the desired pattern accuracy may not be obtained from the viewpoint of optical resolution property. Meanwhile, by using a cationic thermal polymerization initiator in combination with the cationic photopolymerization initiator (A), the amount of cationic photopolymerization initiator (A) can be reduced, thereby achieving both high patterning performance and high curability.

A cationic polymerization initiator with high catalytic function that enables curing at low temperatures can be suitably used as the cationic thermal polymerization initiator. The cationic thermal polymerization initiator is preferably an ionic polymerization initiator. The anion moiety is preferably a gallate-based, phosphorus-based, antimony-based, borate-based, or methide acid-based onium salt. The cationic thermal polymerization initiator is preferably a salt having a cation and an anion represented by formula (1).

The cation in the cationic thermal polymerization initiator is preferably an onium-based cation that can be decomposed by heat. It is more preferable that the cation in the cationic thermal polymerization initiator is an iodonium-based cation, which has excellent cationic polymerization performance and crosslinking reaction performance. Specifically, 4-isopropylphenyl(p-tolyl)iodonium is particularly preferable as the cation in the cationic thermal polymerization initiator.

Furthermore, to prevent salt exchange between the photopolymerization initiators from impairing the catalytic function of each initiator, it is preferable that the anion of the cationic thermal polymerization initiator have the same structure as the anion of the cationic photopolymerization initiator (A).

As for the content of the cationic thermal polymerization initiator in the photosensitive resin composition, the added amount thereof can be freely changed so that the desired curability is demonstrated. However, in particular, to prevent material elution upon contact with ink, it is preferable that the content of the cationic thermal polymerization initiator in the photosensitive resin composition be less than the content of the cationic photopolymerization initiator (A). Specifically, the content of the cationic thermal polymerization initiator in the photosensitive resin composition is, for example, 0.00005 parts by mass to 20 parts by mass, preferably 0.0001 parts by mass to 10 parts by mass, and more preferably 0.05 parts by mass to 0.5 parts by mass, per 100 parts by mass of epoxy resin.

Next, a method for manufacturing a liquid ejection head using this photosensitive resin composition will be described.

### Method for Manufacturing Liquid Ejection Head

A method for manufacturing a liquid ejection head is not particularly limited and can be exemplified by the following method.

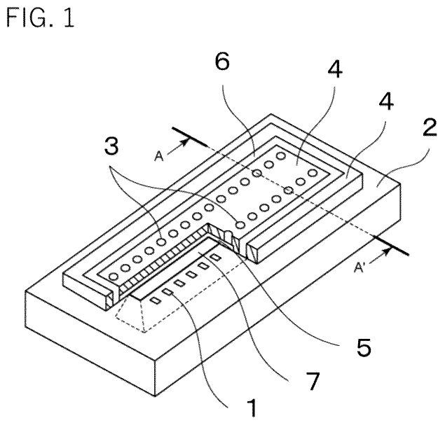

FIG. 1 is a schematic perspective view of a liquid ejection head, such as an inkjet recording head. The liquid ejection head comprises an ejection orifice-forming member 4 in which ejection orifices 3 for ejecting a liquid such as ink are provided on a substrate 2 having a plurality of energy generating elements 1 for ejecting the liquid, and a liquid flow path 5 that communicates with the ejection orifices 3 and retains the liquid. The liquid ejection head may further have grooves 6 formed to reduce internal stress in the ejection orifice-forming member 4. The substrate 2 is also provided with a liquid supply port 7 that supplies liquid such as ink to the flow path 5.

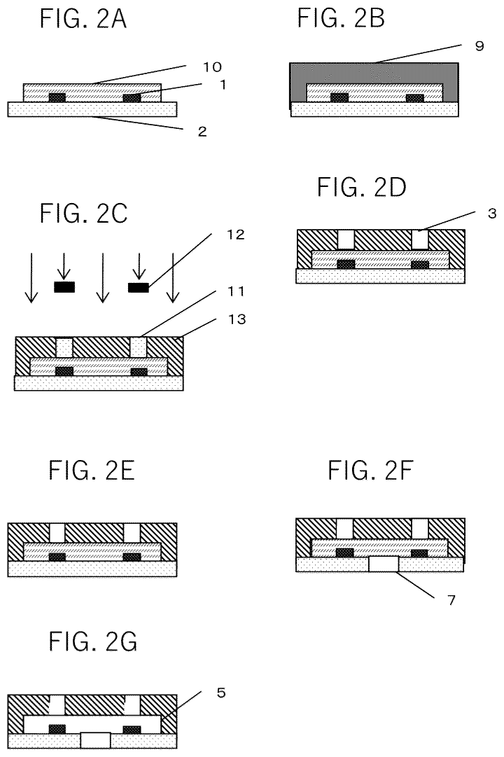

FIGS. 2A to 2G are schematic diagrams showing the manufacturing steps when the liquid ejection head shown in FIG. 1 is viewed from the A-A′ cross section.

The method for manufacturing a liquid ejection head includes a step for forming a mold of a liquid flow path on the substrate. First, a positive-type photosensitive resin layer containing a positive-type photosensitive resin, which can serve as a mold 10 of a liquid flow path, is formed on the substrate 2 on which the energy generating elements 1 have been formed. The positive-type photosensitive resin is not particularly limited. To prevent deterioration of patterning ability due to photosensitizing during exposure of a cationically polymerizable resin layer 9 (described below), the positive-type photosensitive resin is preferably a material with low absorbance to the light used to expose the cationically polymerizable resin layer 9.

For example, where the light is ultraviolet light such as i-line, a material such as polymethyl isopropenyl ketone, which is exposable with DeepUV light, can be used as the positive-type photosensitive resin.

Furthermore, from the viewpoint of further improving pattern accuracy, where the photosensitive resin composition contains a solvent, it is preferable that the mold 10 be insoluble in the solvent contained in the photosensitive resin composition.

The positive-type photosensitive resin layer can be formed, for example, by dissolving the positive-type photosensitive resin in an appropriate solvent, applying the solution to the substrate 2 by spin coating, and then pre-baking to form the positive-type photosensitive resin layer. The thickness of the positive-type photosensitive resin layer corresponds to the height of the flow path and is determined, as appropriate, based on the ejection design of the liquid ejection head, but a preferable thickness is, for example, 5 μm to 22 μm.

Next, the positive-type photosensitive resin layer is patterned to form the mold 10 of a flow path (FIG. 2A). One method for patterning the positive-type photosensitive resin layer is to irradiate the positive-type photosensitive resin layer with active energy rays that can photosensitize the positive-type photosensitive resin through a mask, thereby performing pattern exposure. The exposed portions of the positive-type photosensitive resin layer are then developed using a solvent that can dissolve the resin, followed by a rinse treatment, thereby forming the mold 10.

Next, the cationically polymerizable resin layer 9 is formed using a photosensitive resin composition (FIG. 2B). For example, the photosensitive resin composition for forming the ejection orifice-forming member is applied to the substrate 2 on which the mold 10 has been formed to form the cationically polymerizable resin layer. In the step for forming the cationically polymerizable resin layer 9, for example, the photosensitive resin composition may be applied to form a coating film. After application, heating may be performed as needed. Heating temperatures include, for example, 50° C. to 90° C. and 55° C. to 70° C. Heating times include, for example, 1 min to 20 min and 5 min to 15 min.

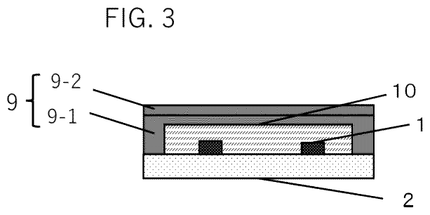

There are no particular limitations on the application method, as long as it forms a uniform film. For example, a spin coating method and a slit coating method can be used. Furthermore, to improve accuracy in the nozzle depth direction, as shown in FIG. 3, the cationically polymerizable resin layer 9 may be formed in a layered configuration by forming a lower layer 9-1 from the photosensitive resin composition by spin coating or slit coating, and then forming an upper layer 9-2 of the identical photosensitive resin composition by a dry film manufacturing method.

Specifically, in the step for applying the photosensitive resin composition that will form the ejection orifice-forming member onto a substrate with a mold formed thereon to form the cationically polymerizable resin layer, the following method is preferably used. That is, it is preferable to form a dry film of a photosensitive resin composition having the same composition as the applied photosensitive resin composition and then paste the resulting dry film onto the applied photosensitive resin composition to form the cationically polymerizable resin layer.

The thickness of the cationically polymerizable resin layer 9 is determined, as appropriate, based on the ejection design of the liquid ejection head, but is preferably, for example, 10 μm to 30 μm.

Next, if necessary, a water-repellent material may be applied to the cationically polymerizable resin layer to provide a water-repellent layer. The water-repellent material is preferably applied after the formation of the cationically polymerizable resin layer and before exposure. For example, a water-repellent layer (not shown) is preferably provided to prevent ink accumulation near the ejection orifices. A cationically polymerizable perfluoroalkyl composition, a cationically polymerizable perfluoropolyether composition, a silicone composition having a dimethylsiloxane structure, and a silane compound having a perfluoroalkyl group can be suitably used as the water-repellent component of the water-repellent material. The water-repellent component is preferably a silane compound having a perfluoroalkyl group, more preferably an alkoxysilane compound having a perfluoroalkyl group, and even more preferably an alkoxysilane compound having one perfluoroalkyl group and three alkoxy groups. In general, these compositions exhibit segregation of water-repellent groups at the air interface upon baking after application, which can enhance water repellency.

Furthermore, it is preferable that the cationically polymerizable resin layer and the water-repellent layer be compatible and could be patterned simultaneously to prevent unevenness in the shape of ejection orifices composed of these layers during the exposure and development steps described hereinbelow. Therefore, the water-repellent material preferably contains a solvent capable of dissolving the photosensitive resin composition, and more preferably contains a solvent having a polar group. Examples of solvents having a polar group include alcohols such as methanol and ethanol. Monohydric alcohols are preferred, and ethanol is more preferred.

The thickness of the water-repellent layer is preferably 0.1 μm to 3.0 μm, and more preferably 0.2 μm to 2.0 μm.

Next, a step for forming the ejection orifice-forming member is performed by exposing and developing the cationically polymerizable resin layer. First, a step for exposing the cationically polymerizable resin layer 9 is implemented (FIG. 2C). A photomask 12 tailored to the desired shape of the ejection orifices 3 may be used for exposure. The exposed portions 13 become the ejection orifice-forming member 4, and the unexposed portions 11 become the ejection orifices 3.

When using a cationic curing photosensitive resin composition as described above, a heating step may be performed after exposure at a wavelength that promotes the photocuring reaction of the resin composition. At this time, from the viewpoint of preventing the catalyst from diffusing into unexposed areas due to post-exposure retention and improving patterning accuracy, it is preferable to perform a heat treatment immediately after exposure. The post-exposure heat treatment temperature is preferably adjusted to 70° C. or higher, as long as it promotes the reaction so that the pattern of exposed portions is not removed during the development step. Examples of suitable temperatures include 70° C. to 120° C. and 80° C. to 110° C.

Next, the exposed cationically polymerizable resin layer 9 is developed to form the ejection orifice-forming member having ejection orifices 3 (FIG. 2D). This allows the ejection orifices and the flow path to be formed from the same material. In other words, a single layer of photosensitive resin composition is preferable. Therefore, compared to the case of forming the ejection orifices and the flow path from separate materials, there is no risk of peeling at the interface between the materials.

A solvent capable of dissolving uncured epoxy resin is suitable as a developer to be used for development. Specifically, ester solvents or ketone solvents such as propylene glycol monomethyl ether acetate, methyl ethyl ketone, and methyl isobutyl ketone may be used.

Furthermore, a heat treatment may be performed to promote the curing of the photosensitive resin composition (FIG. 2E). For example, where the photosensitive resin composition contains a cationic thermal polymerization initiator, it is preferable to perform a post-development heat treatment at a temperature higher than the reaction initiation temperature of the cationic thermal polymerization initiator. Specifically, heating is preferably performed at a temperature of 100° C. or higher, 130° C. or higher, or 140° C. or higher. Examples of heating temperatures include 100° C. to 170° C., 130° C. to 160° C., and 140° C. to 150° C. Examples of heating times include 1 min to 10 min.

Furthermore, it is preferable to include a step for baking at 140° C. or higher after the step for exposing and developing the cationically polymerizable resin layer to form the ejection orifice-forming member. This heating treatment may be a step for baking at 140° C. or higher, or the main baking described below may be a step for baking at 140° C. or higher, or both the heating treatment and the main baking described below may be a step for baking at 140° C. or higher. Baking at 140° C. or higher can promote curing of the photosensitive resin composition, making it easier to prevent peeling of components.

Next, as shown in FIG. 2F, a liquid supply port, which is an ink supply port that penetrates the substrate 2, is formed. A method for forming the ink supply port is not particularly limited, but it can be performed by anisotropic etching using an etching solution-resistant resin composition as an etching mask.

Next, as shown in FIG. 2G, the mold 10 is removed to form the flow path 5. Because the mold 10 is a positive-type photosensitive resin layer, it may be removed by exposure and development. Furthermore, it is preferable to perform the main baking. The main baking temperature is preferably higher than the reaction initiation temperature of the cationic thermal polymerization initiator. Examples of heating temperatures include 100° C. to 250° C., 140° C. to 230° C., and 180° C. to 220° C. The heating time is preferably 30 min or more, and more preferably 30 min to 200 min. As mentioned above, this main baking may be a step for baking at 140° C. or higher.

To prevent cracks due to increased film stress during the main baking, the film stress of the resulting cured product is preferably 20 MPa or less. Because increased film stress can occur due to thermal shrinkage and cure shrinkage, the heating temperature during the main baking and the amount of unreacted components added have a dominant influence. Therefore, a plasticizer that does not react under light irradiation or heat can be added. The more plasticizer added, the more effectively the increase in film stress can be prevented, allowing for higher temperatures during the main baking. For example, where 10 parts by mass to 40 parts by mass of plasticizer is added per 100 parts by mass of epoxy resin, heat treatment at 180° C. to 200° C. can be performed during the main baking. Examples of plasticizers include organic fluorine compounds and indene resins that do not contain epoxy groups.

After forming the flow path 5, the liquid ejection head is completed by joining components for liquid supply (not shown), making electrical connections (not shown) to drive the energy generating elements 1, etc.

In other words, the liquid ejection head according to the present disclosure is a liquid ejection head in which an ejection orifice-forming member that forms ejection orifices for ejecting a liquid and a flow path for the liquid that communicates with the ejection orifices is formed on a substrate, wherein
the ejection orifice-forming member is a cured product of a photosensitive resin composition;
the photosensitive resin composition includes at least one epoxy resin selected from the group consisting of an alicyclic epoxy resin and a glycidyl epoxy resin, and a cationic photopolymerization initiator (A),
the cationic photopolymerization initiator (A) is a salt having an anion represented by the following formula (1), and
a molar absorption coefficient of the cationic photopolymerization initiator (A) at a wavelength of 365 nm is 0.1 L/mol·cm or greater.

By using the method for manufacturing a liquid ejection head described above, it is possible to manufacture a liquid ejection head in which ink ejection orifices and ink flow path are formed with high precision.

### EXAMPLES

The present disclosure will be described in detail below using examples and comparative examples. However, the present disclosure is not limited to the configurations embodied in these examples. Furthermore, “parts” used in the examples and comparative examples means “parts by mass” unless otherwise specified.

Examples 1 to 6, 8 to 22, and 24, Comparative Examples 1 to 3 Fabrication of Inkjet Recording Head

The fabrication of an inkjet recording head as an example of liquid ejection head will be described below with reference to FIGS. 2A to 2G. The liquid ejection heads of Examples 1 to 6, 8 to 22, 24, and Comparative Examples 1 to 3 were fabricated using the materials listed in Tables 1 to 4, respectively.

First, polymethyl isopropenyl ketone (product name “ODUR-1010”, manufactured by Tokyo Ohka Kogyo Co., Ltd.) was applied by spin coating to a Si substrate 2 equipped with energy generating elements 1 as a positive-type photosensitive resin for forming an ink flow path mold 10. A heat treatment at 120° C. was performed for 6 min to form a 14 μm-thick positive-type photosensitive resin layer.

Next, a pattern of ink flow paths was exposed using a UX3000 exposure device (trade name, manufactured by Ushio Inc.), and the exposed portions of the positive-type photosensitive resin layer were developed using MIBK (methyl isobutyl ketone), followed by a rinse treatment with IPA (isopropyl alcohol) to form the mold 10 (FIG. 2A).

Next, a photosensitive resin composition was applied to the mold 10 and substrate 2 by spin coating, followed by heat treatment at 60° C. for 9 min, thereby forming a 25 μm-thick cationically polymerizable resin layer 9 for use as an ejection orifice component (FIG. 2B).

In the examples and comparative examples, the cationically polymerizable resin layers 9 were made from the photosensitive resin compositions including components listed in Tables 1 to 4 below.

Furthermore, a water-repellent material was applied to the surface of the cationically polymerizable resin layer 9 to a thickness of 0.5 μm. The composition of the water-repellent material is listed in Tables 1 to 4.

Next, using a photomask 12, exposure was performed using an i-line stepper at 4000 J/m2 so that the resulting openings in the surface of the cationically polymerizable resin layer 9 had a diameter of 8.3 μm. This patterning was performed simultaneously on the cationically polymerizable resin layer and the water-repellent material. This was then followed by heat treatment at 90° C. for 4 min (FIG. 2C).

Then, development was performed to form ejection orifices 3. The development was performed using a mixture of MIBK and xylene, followed by rinsing with xylene (FIG. 2D). This was followed by heat treatment at 140° C. for 4 min (FIG. 2E).

Next, an etching mask was formed on the back surface of the substrate 2, and the silicon substrate was anisotropically etched to form an ink supply port 7 (FIG. 2F). To protect the ejection orifice formation surface from the etching solution, a protective film (OBC, manufactured by Tokyo Ohka Kogyo Co., Ltd.) was applied to the photosensitive resin layer.

The protective film was then dissolved and removed with xylene. After that, the entire surface was exposed to light through a negative resist at an exposure dose of 250,000 mJ/cm2 using a Deep-UV exposure system UX-3000 manufactured by Ushio Inc., thereby solubilizing the mold 10. The mold 10 was then dissolved and removed by immersing in methyl lactate while applying ultrasonic waves, thereby forming the flow path 5 (FIG. 2G). This was followed by a final baking at 200° C. for 60 min.

Next, the inkjet recording head was completed by performing mounting steps such as joining components for ink supply (not shown), making electrical connections for driving the energy generating elements 1 (not shown), and sealing for protecting the electrical connections (not shown).

### Example 7

### Fabrication of Inkjet Recording Head

The heating treatment after the development treatment (FIG. 2E) was performed at 100° C. for 4 min, and the temperature of main baking after dissolving and removing the mold material 10 was set to 100° C. The inkjet recording head of Example 7 was fabricated using the same method as in Example 1 for all other steps.

### Example 23

### Fabrication of Inkjet Recording Head

In the step for forming the cationically polymerizable resin layer 9, the cationically polymerizable resin layer 9 was formed on a mold 10 by spin coating to a thickness sufficient to cover the mold 10, as shown in FIG. 3, and a dry film of the cationically polymerizable resin layer 9 was then pasted on the cationically polymerizable resin layer 9. The inkjet recording head of Example 23 was fabricated using the same method as in Example 1 for all other steps.

### Examples 1-24 and Comparative Examples 1 to 3

The following evaluations were performed using each of the resulting inkjet recording heads.

### Evaluation Method for Peeling/Mask Reproducibility

Peeling

A peeling test was performed to evaluate adhesiveness.

Ink was prepared with weight ratios of pure water/diethylene glycol/isopropyl alcohol/lithium acetate/food black dye=79.4/15/3/0.1. The completed inkjet recording head was immersed in this ink at 60° C. for three months, and then the bonding state between the ejection orifice-forming member 4 and the substrate was evaluated. The evaluation criteria are as follows:
A: Peeling of the ejection orifice-forming material from the substrate was not observed over the entire head surface.
B: Peeling of the ejection orifice-forming material from the substrate was observed over an area of less than 30% of the entire head surface.
C: Peeling of the ejection orifice-forming material from the substrate was observed over an area of less than 50% of the entire head surface.
D: Peeling of the ejection orifice-forming material from the substrate was observed over an area of 50% or more of the entire head surface.

### Mask Reproducibility

Mask reproducibility was checked as an evaluation of pattern accuracy. A mask reproducibility evaluation sample was prepared using the same method, except that the photomask 12 or forming ejection orifices was replaced with a mask for mask reproducibility evaluation with a line/space pattern width of 20 μm.

The pattern width on the unexposed portions of the substrate was observed using a scanning electron microscope (product name: S-4300, manufactured by Hitachi High-Technologies Corporation). The external appearance was evaluated according to the following criteria.
A: The line/space pattern width is 20 μm, and a linear pattern is obtained. Both the upper surface shape and the cross-sectional shape reproduce the exposure photomask.
B: The line/space pattern width is 18 μm to 19 μm or 21 μm to 22 μm, and a linear pattern is obtained. The upper surface shape does not reproduce the photomask shape slightly. Alternatively, slight thinning of the pattern can be confirmed in the cross-sectional shape.
C: The line/space pattern width is 16 μm to 17 μm or 23 μm to 24 μm, and a linear pattern is obtained. The upper surface shape does not reproduce the photomask shape slightly. Alternatively, slight thinning of the pattern can be confirmed in the cross-sectional shape.
D: The line/space pattern width is less than 16 μm or greater than 24 μm, or the pattern has an overhanging shape. The upper surface shape and/or the cross-sectional shape does not reproduce the exposure photomask.
   Method for Evaluating Printing with Inkjet Recording Head

The evaluation ink was poured into a tank, and the printing characteristics were evaluated. Printing was evaluated according to the following criteria. Landing accuracy was evaluated as the deviation between the actual landing position of a droplet on a recording medium and the target landing position.
A: Landing accuracy is 3 μm or less
B: Landing accuracy is more than 3 μm and 5 μm or less
C: Landing accuracy is more than 5 μm and 7 μm or less
D: Landing accuracy is more than 7 μm

### Evaluation Results

The results are shown in Tables 1 to 4. All examples demonstrated excellent adhesiveness and pattern accuracy, and good printing performance was also achieved. Examples 20 and 22 exhibited particularly excellent print quality. Meanwhile, print quality was poor in Comparative Examples 1 to 3.

The technique described herein can serve as a substitute for acid generators containing SbF₆⁻. In other words, the technologies described in this specification have the potential to contribute to the achievement of a sustainable society, such as a decarbonized society/circular society.

TABLE 1

| | | | Example 1 | Example 2 | Example 3 | Example 4 |
|---|---|---|---|---|---|---|
| Photosensitive | Epoxy resin | Product name | EHPE-3150 | EHPE-3150 | EHPE-3150 | EHPE-3150 |
| resin composition | | Type of resin | Alicyclic | Alicyclic | Alicyclic | Alicyclic |
| | | | epoxy resin | epoxy resin | epoxy resin | epoxy resin |
| | | State (normal | Solid | Solid | Solid | Solid |
| | | temperature) | | | | |
| | | Epoxy equivalent | 170~190 | 170~190 | 170~190 | 170~190 |
| | | Amount added/parts | 100 | 100 | 100 | 100 |
| | Photoinitiator \textcircled{1} | Cation structure | c1 | c2 | c3 | c4 |
| | | Anion structure | a1 | a1 | a1 | a1 |
| | | Mole absorption | 0.6 | 0.6 | 4.8 | 4.8 |
| | | coefficient | | | | |
| | | Amount added/parts | 3 | 3 | 3 | 3 |
| | Photoinitiator\textcircled{2} | Cation structure | | | | |
| | (quencher) | Anion structure | | | | |
| | | Amount added/parts | | | | |
| | Thermal initiator | Cation structure | | | | |
| | | Anion structure | | | | |
| | | Amount added/parts | | | | |
| | Solvent | Ester system | | | | |
| | | Amount added/parts | | | | |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | Ethanol | Ethanol | Ethanol |
| | | Amount added/parts | 95 parts | 95 parts | 95 parts | 95 parts |
| Evaluation | Peeling | | B | B | B | B |
| | Mask reproducibility/% | | A | A | A | A |
| | Print evaluation | | B | B | B | B |
| | | | Example 5 | Example 6 | Example 7 | Example 8 |
| Photosensitive | Epoxy resin | Product name | EHPE-3150 | EHPE-3150 | EHPE-3150 | EHPE-3150 |
| resin composition | | Type of resin | Alicyclic | Alicyclic | Alicyclic | Alicyclic |
| | | | epoxy resin | epoxy resin | epoxy resin | epoxy resin |
| | | State (normal | Solic | Solid | Solid | Solid |
| | | temperature) | | | | |
| | | Epoxy equivalent | 170~190 | 170~190 | 170~190 | 170~190 |
| | | Amount added/parts | 100 | 100 | 100 | 100 |
| | Photoinitiator \textcircled{1} | Cation structure | c1 | c1 | c1 | c1 |
| | | Anion structure | a1 | a1 | a1 | a2 |
| | | Mole absorption | 0.6 | 0.6 | 0.6 | 0.5 |
| | | coefficient | | | | |
| | | Amount added/parts | 0.05 | 20 | 3 | 3 |
| | Photoinitiator\textcircled{2} | Cation structure | | | | |
| | (quencher) | Anion structure | | | | |
| | | Amount added/parts | | | | |
| | Thermal initiator | Cation structure | | | | |
| | | Anion structure | | | | |
| | | Amount added/parts | | | | |
| | Solvent | Ester system | | | | |
| | | Amount added/parts | | | | |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | Ethanol | Ethanol | Ethanol |
| | | Amount added/parts | 95 parts | 95 parts | 95 parts | 95 parts |

| | | | | | |
|---|---|---|---|---|---|
| Evaluation | Peeling | C | C | C | B |
| | Mask reproducibility/% | A | C | A | A |
| | Print evaluation | C | C | C | B |

TABLE 2

| | | | Example 9 | Example 10 | Example 11 | Example 12 |
|---|---|---|---|---|---|---|
| Photosensitive | Epoxy resin | Product name | EX-861 | EX-171 | DE-102 | DE-103 |
| resin composition | | Type of resin | Glycidyl-type | Glycidyl-type | Alicyclic | Alicyclic |
| | | | epoxy resin | epoxy resin | epoxy resin | epoxy resin |
| | | State (normal | Solid | Solid | Solid | Solid |
| | | temperature) | | | | |
| | | Epoxy equivalent | 551 | 971 | — | — |
| | | Amount added/parts | 100 | 100 | 100 | 100 |
| | Photoinitiator\textcircled{1} | Cation structure | c1 | c1 | c1 | c1 |
| | | Anion structure | a1 | a1 | a1 | a1 |
| | | Mole absorption | 0.6 | 0.6 | 0.6 | 0.6 |
| | | coefficient | | | | |
| | | Amount added/parts | 3 | 3 | 3 | 3 |
| | Photoinitiator\textcircled{2} | Cation structure | | | | |
| | (quencher) | Anion structure | | | | |
| | | Mole absorption | | | | |
| | | coefficient | | | | |
| | | Amount added/parts | | | | |
| | Thermal initiator | Cation structure | | | | |
| | | Anion structure | | | | |
| | | Amount added/parts | | | | |
| | Solvent | Ester system | | | | |
| | | Amount added/parts | | | | |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | Ethanol | Ethanol | Ethanol |
| | | Amount added/parts | 95 parts | 95 parts | 95 parts | 95 parts |

| | | | | | |
|---|---|---|---|---|---|
| Evaluation | Peeling | B | C | B | B |
| | Mask reproducibility/% | B | C | B | B |
| | Print evaluation | B | C | B | B |

| | | | Example 13 | Example 14 | Example 15 | Example 16 |
|---|---|---|---|---|---|---|
| Photosensitive | Epoxy resin | Product name | EX-321L | EHPE-3150 | EHPE-3150 | EHPE-3150 |
| resin composition | | Type of resin | Glycidyl-type | Alicyclic | Alicyclic | Alicyclic |
| | | | epoxy resin | epoxy resin | epoxy resin | epoxy resin |
| | | State (normal | Liquid | Solid | Solid | Solid |
| | | temperature) | | | | |
| | | Epoxy equivalent | 130 | 170~190 | 170~190 | 170~190 |
| | | Amount added/parts | 100 | 100 | 100 | 100 |
| | Photoinitiator\textcircled{1} | Cation structure | c1 | c1 | c1 | c1 |
| | | Anion structure | a1 | a1 | a1 | a1 |
| | | Mole absorption | 0.6 | 0.6 | 0.6 | 0.6 |
| | | coefficient | | | | |
| | | Amount added/parts | 3 | 3 | 3 | 3 |
| | Photoinitiator\textcircled{2} | Cation structure | | | | |
| | (quencher) | Anion structure | | | | |
| | | Mole absorption | | | | |
| | | coefficient | | | | |
| | | Amount added/parts | | | | |
| | Thermal initiator | Cation structure | | | c5 | c5 |
| | | Anion structure | | | a1 | a1 |
| | | Amount added/parts | | | 0.00005 | 0.1 |
| | Solvent | Ester system | | | | |
| | | Amount added/parts | | | | |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | PGMEA | Ethanol | Ethanol |
| | | Amount added/parts | 95 parts | 95 parts | 95 parts | 95 parts |

| | | | | | |
|---|---|---|---|---|---|
| Evaluation | Peeling | C | B | B | A |
| | Mask reproducibility/% | C | C | A | B |
| | Print evaluation | C | C | B | B |

TABLE 3

| | | | Example 17 | Example 18 | Example 19 | Example 20 |
|---|---|---|---|---|---|---|
| Photosensitive | Epoxy resin | Product name | EHPE- | EHPE-3150 | EHPE-3150 | EHPE-3150 |
| resin composition | | Type of resin | Alicyclic | Alicyclic | Alicyclic | Alicyclic |
| | | | epoxy resin | epoxy resin | epoxy resin | epoxy resin |
| | | State (normal | Solid | Solid | Solid | Solid |
| | | temperature) | | | | |
| | | Epoxy equivalent | 170~190 | 170~190 | 170~190 | 170~190 |
| | | Amount added/parts | 100 | 100 | 100 | 100 |
| | Photoinitiator\textcircled{1} | Cation structure | c1 | c1 | c1 | c1 |
| | | Anion structure | a1 | a1 | a1 | a1 |
| | | Mole absorption | 0.6 | 0.6 | 0.6 | 0.6 |
| | | coefficient | | | | |
| | | Amount added/parts | 3 | 3 | 3 | 3 |
| | Photoinitiator\textcircled{2} | Cation structure | | c6 | c6 | c6 |
| | (quencher) | Anion structure | | a4 | a4 | a4 |
| | | Mole absorption | | 0 | 0 | 0 |
| | | coefficient | | | | |
| | | Amount added/parts | | 0.1 | 0.1 | 0.1 |
| | Thermal initiator | Cation structure | c5 | Structure | c5 | c5 |
| | | | | is unclear | | |
| | | | | SI-150 | | |
| | | Anion structure | a1 | a3 | a1 | a1 |
| | | Amount added/parts | 20 | 0.1 | 0.1 | 0.1 |
| | Solvent | Ester system | | | | Ethyl |
| | | Amount added/parts | | | | acetate 3 |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | Ethanol | Ethanol | Ethanol |
| | | Amount added/parts | 95 parts | 95 parts | 95 parts | 95 parts |
| Evaluation | Peeling | | B | B | B | A |
| | Mask reproducibility/% | | C | C | A | A |
| | Print evaluation | | C | B | B | A |
| | | | Example 21 | Example 22 | Example 23 | Example 24 |
| Photosensitive | Epoxy resin | Product name | EHPE-3150 | EHPE-3150 | EHPE-3150 | EHPE-3150 |
| resin composition | | Type of resin | Alicyclic | Alicydic | Alicyclic | Alicyclic |
| | | | epoxy resin | epoxy resin | epoxy resin | epoxy resin |
| | | State (normal | Solid | Solid | Solid | Solid |
| | | temperature) | | | | |
| | | Epoxy equivalent | 170~190 | 170~190 | 170~190 | 170~190 |
| | | Amount added/parts | 100 | 100 | 100 | 100 |
| | Photoinitiator\textcircled{1} | Cation structure | c1 | c1 | c1 | C7 |
| | | Anion structure | a1 | a1 | a1 | a1 |
| | | Mole absorption | 0.6 | 0.6 | 0.6 | 0.6 |
| | | coefficient | | | | |
| | | Amount added/parts | 3 | 3 | 3 | 3 |
| | Photoinitiator\textcircled{2} | Cation structure | C6 | c6 | | |
| | (quencher) | Anion structure | a4 | a4 | | |
| | | Mole absorption | 0 | 0 | | |
| | | coefficient | | | | |
| | | Amount added/parts | 0.1 | 0.1 | | |
| | Thermal initiator | Cation structure | c5 | c5 | | |
| | | Anion structure | a1 | a1 | | |
| | | Amount added/parts | 0.1 | 0.1 | | |
| | Solvent | Ester system | Ethyl | Propylene | | |
| | | Amount added/parts | acetate 25 | carbonate 3 | | |
| | | Other | Xylene | Xylene | Xylene | Xylene |
| | | Amount added/parts | 50 | 50 | 50 | 50 |
| Water-repellent | Water-repellent | Compound name | h1 | h1 | h1 | h1 |
| material | component | Amount added/parts | 5 parts | 5 parts | 5 parts | 5 parts |
| | Solvent | Compound name | Ethanol | Ethanol | Ethanol | Ethanol |
| | | Amount added/parts | 95 parts | 95 parts | 95 parts | 95 parts |

| | | | | | |
|---|---|---|---|---|---|
| Evaluation | Peeling | A | A | B | B |
| | Mask reproducibility/% | C | A | B | A |
| | Print evaluation | B | A | B | B |

TABLE 4

| | | | Comparative | Comparative | Comparative |
|---|---|---|---|---|---|
| | | | Example 1 | Example 2 | Example 3 |
| Photosensitive | Epoxy resin | Product name | EHPE-3150 | jER157S70 | jER157S70 |
| resin | | Type of resin | Alicyclic epoxy | Bisphenol A | Bisphenol A |
| composition | | | resin | epoxy resin | epoxy resin |
| | | State (normal | Solid | Solid | Solid |
| | | temperature) | | | |
| | | Epoxy equivalent | 170~190 | 170~190 | 170~190 |
| | | Amount added/parts | 100 | 100 | 100 |
| | Photoinitiator\textcircled{1} | Cation structure | c1 | c1 | c1 |
| | | Anion structure | a5 | a5 | a1 |
| | | Mole absorption | 0.6 | 0 | 0 |
| | | coefficient | | | |
| | | Amount added/parts | 3 | 3 | 3 |
| | Photoinitiator\textcircled{2} | Cation structure | | | |
| | (quencher) | Anion structure | | | |
| | | Mole absorption | | | |
| | | coefficient | | | |
| | | Amount added/parts | | | |
| | Thermal initiator | Cation structure | | | |
| | | Anion structure | | | |
| | | Amount added/parts | | | |
| | Solvent | Ester system | | | |
| | | Amount added/parts | | | |
| | | Other | Xylene | Xylene | Xylene |
| | | Amount added/parts | 50 | 50 | 50 |
| Water- | Water-repellent | Compound name | h1 | h1 | h1 |
| repellent | component | Amount added/parts | 5 parts | 5 parts | 5 parts |
| material | Solvent | Compound name | Ethanol | Ethanol | Ethanol |
| | | Amount added/parts | 95 parts | 95 parts | 95 parts |

| | | | | |
|---|---|---|---|---|
| Evaluation | Peeling | B | B | D |
| | Mask reproducibility/% | D | D | D |
| | Print evaluation | D | D | D |

The materials in the tables are as follows.
EHPE-3150: Manufactured by Daicel Chemical Industries, Ltd.
EX-861: Denacol EX-861, manufactured by Nagase ChemteX Corporation
EX-171: Denacol EX-171, manufactured by Nagase ChemteX Corporation
EX-321L: Denacol EX-321L, manufactured by Nagase ChemteX Corporation
DE-102: Manufactured by ENEOS Corporation
DE-103: Manufactured by ENEOS Corporation
jER157S70: Manufactured by Mitsubishi Chemical Corporation
SI-150: Manufactured by Sanshin Chemical Industry Co., Ltd.

Here, a1 to a5, c1 to c7, and h1 in the tables represent the following structures.
a1: Tetrakis(pentafluorophenyl)gallate

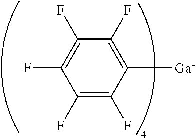

a2: Tetrakis(3,5-bis(trifluoromethyl)phenyl)gallate

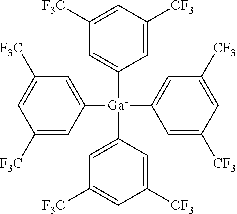

a4: Tosylate

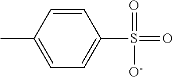

a5: Tetrakis(pentafluorophenyl) borate

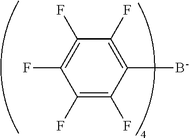

c1: [4-(4-biphenylylthio)phenyl]-4-biphenylylphenylsulfonium

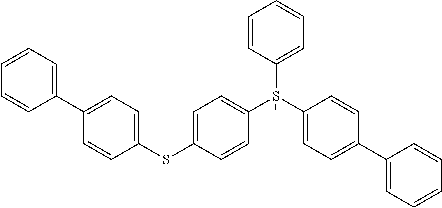

c2: 4-hydroxyphenyl-methyl-1-naphthylmethylsulfonium
c3: 2-[(di-p-tolyl)sulfonio]thioxanthone
c4: 2-[(diphenyl)sulfonio]thioxanthone
c5: 4-isopropylphenyl(p-tolyl)iodonium
c6: triphenylsulfonium

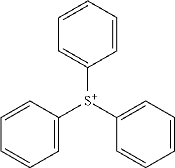 [SMILES: c1ccc([S+](c2ccccc2)c2ccccc2)cc1]

c7: 2-[(phenyl)sulfinyl]-9,9-dimethylfluorene

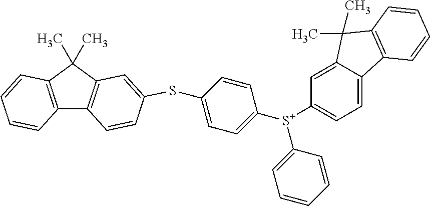 [SMILES: CC1(C)c2ccccc2-c2ccc(Sc3ccc([S+](c4ccccc4)c4ccc5c(c4)C(C)(C)c4ccccc4-5)cc3)cc21]

h1: triethoxy-1H,1H,2H,2H-heptadecafluorodecylsilane

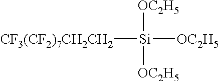

With the present disclosure, it is possible to provide a method for manufacturing a liquid ejection head in which high pattern precision is combined with high adhesiveness and which has good printing accuracy, and also provide such a liquid ejection head.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-210496, filed Dec. 3, 2024, which is hereby incorporated by reference herein in its entirety.

What is claimed is:

1. A method for manufacturing a liquid ejection head in which an ejection orifice-forming member that forms ejection orifices for ejecting a liquid and a flow path for the liquid that communicates with the ejection orifices is formed on a substrate, the manufacturing method comprising:
forming a mold for the flow path for the liquid on the substrate;
coating a photosensitive resin composition for forming the ejection orifice-forming member onto the substrate, on which the mold has been formed, to form a cationically polymerizable resin layer; and
exposing and developing the cationically polymerizable resin layer to form the ejection orifice-forming member, wherein
the photosensitive resin composition comprises at least one epoxy resin selected from the group consisting of an alicyclic epoxy resin and a glycidyl epoxy resin, and a cationic photopolymerization initiator (A),
the cationic photopolymerization initiator (A) is a salt having an anion represented by a following formula (1), and
a molar absorption coefficient of the cationic photopolymerization initiator (A) at a wavelength of 365 nm is at least 0.1 L/mol·cm: 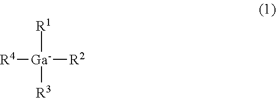
in formula (1), R¹ to R⁴ are each independently an alkyl group having 1 to 18 carbon atoms or Ar, provided that at least one of the R¹ to R⁴ is Ar,
the Ar is an aryl group having 6 to 14 carbon atoms (not including the number of carbon atoms in following substituents), and some of hydrogen atoms in the aryl group may be substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR⁶, an acyl group represented by R⁷CO—, an acyloxy group represented by R⁸COO—, an alkylthio group or arylthio group represented by —SR⁹, an amino group represented by —NR¹⁰R¹¹, or a halogen atom, the R⁶ to R⁹ are each independently an alkyl group having 1 to 8 carbon atoms or an aryl group having 6 to 14 carbon atoms, and the R¹⁰ and R¹¹ are each independently a hydrogen atom, an alkyl group having 1 to 8 carbon atoms, or an aryl group having 6 to 14 carbon atoms.

2. The method for manufacturing a liquid ejection head according to claim 1, wherein
the cationic photopolymerization initiator (A) is a salt having a cation and an anion represented by the formula (1), and
the cation of the salt is an onium-based cation.

3. The method for manufacturing a liquid ejection head according to claim 2, wherein
the cation is a sulfonium-based cation.

4. The method for manufacturing a liquid ejection head according to claim 1, wherein a content of the cationic photopolymerization initiator (A) in the photosensitive resin composition is 0.1 parts by mass to 10 parts by mass per 100 parts by mass of the epoxy resin.

5. The method for manufacturing a liquid ejection head according to claim 1, wherein the epoxy resin is solid at room temperature.

6. The method for manufacturing a liquid ejection head according to claim 1, wherein the epoxy resin has an epoxy equivalent weight (g/eq.) of not more than 500.

7. The method for manufacturing a liquid ejection head according to claim 1, wherein
the method for manufacturing a liquid ejection head comprises applying a water-repellent material to the cationically polymerizable resin layer after forming the cationically polymerizable resin layer, and
the water-repellent material comprises a solvent having a polar group.

8. The method for manufacturing a liquid ejection head according to claim 7, wherein
in the step for exposing and developing the cationically polymerizable resin layer to form the ejection orifice-forming member,
the cationically polymerizable resin layer and the water-repellent material are patterned simultaneously.

9. The method for manufacturing a liquid ejection head according to claim 1, wherein the photosensitive resin composition further comprises a cationic thermal polymerization initiator.

10. The method for manufacturing a liquid ejection head according to claim 9, wherein the cationic thermal polymerization initiator is a salt having an anion represented by the formula (1).

11. The method for manufacturing a liquid ejection head according to claim 10, wherein the anion of the cationic thermal polymerization initiator has the same structure as the anion of the cationic photopolymerization initiator (A).

12. The method for manufacturing a liquid ejection head according to claim 10, wherein the cation of the cationic thermal polymerization initiator is an iodonium-based cation.

13. The method for manufacturing a liquid ejection head according to claim 10, wherein a content of the cationic thermal polymerization initiator in the photosensitive resin composition is less than a content of the cationic photopolymerization initiator (A).

14. The method for manufacturing a liquid ejection head according to claim 10, wherein a content of the cationic thermal polymerization initiator in the photosensitive resin composition is 0.0001 parts by mass to 10 parts by mass per 100 parts by mass of the epoxy resin.

15. The method for manufacturing a liquid ejection head according to claim 1, wherein the photosensitive resin composition further comprises a cationic photopolymerization initiator (B) different from the cationic photopolymerization initiator (A) and having a lower acid strength than the cationic photopolymerization initiator (A).

16. The method for manufacturing a liquid ejection head according to claim 15, wherein a content of the cationic photopolymerization initiator (B) in the photosensitive resin composition is 0.01 times to 0.5 times a content of the cationic photopolymerization initiator (A) by mass.

17. The method for manufacturing a liquid ejection head according to claim 1, wherein the photosensitive resin composition comprises 0.1 parts by mass to 10 parts by mass of an ester solvent per 100 parts by mass of the epoxy resin.

18. The method for manufacturing a liquid ejection head according to claim 1, wherein
in the forming the cationically polymerizable resin layer,
a dry film of a photosensitive resin composition having the same composition as the coated photosensitive resin composition is formed, and the resulting dry film is attached onto the coated photosensitive resin composition to form the cationically polymerizable resin layer.

19. A liquid ejection head in which an ejection orifice-forming member that forms ejection orifices for ejecting a liquid and a flow path for the liquid that communicates with the ejection orifices is formed on a substrate, wherein
the ejection orifice-forming member is a cured product of a photosensitive resin composition;
the photosensitive resin composition comprises at least one epoxy resin selected from the group consisting of an alicyclic epoxy resin and a glycidyl epoxy resin, and a cationic photopolymerization initiator (A),
the cationic photopolymerization initiator (A) is a salt having an anion represented by a following formula (1), and
a molar absorption coefficient of the cationic photopolymerization initiator (A) at a wavelength of 365 nm is at least 0.1 L/mol·cm, 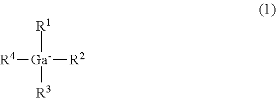
in formula (1), R¹ to R⁴ are each independently an alkyl group having 1 to 18 carbon atoms or Ar, provided that at least one of the R¹ to R⁴ is Ar,
the Ar is an aryl group having 6 to 14 carbon atoms (not including the number of carbon atoms in following substituents), and some of hydrogen atoms in the aryl group may be substituted with an alkyl group having 1 to 18 carbon atoms, an alkyl group having 1 to 8 carbon atoms substituted with a halogen atom, an alkenyl group having 2 to 18 carbon atoms, an alkynyl group having 2 to 18 carbon atoms, an aryl group having 6 to 14 carbon atoms, a nitro group, a hydroxyl group, a cyano group, an alkoxy group or aryloxy group represented by —OR⁶, an acyl group represented by R⁷CO—, an acyloxy group represented by R⁸COO—, an alkylthio group or arylthio group represented by —SR⁹, an amino group represented by —NR¹⁰R¹¹, or a halogen atom, the R⁶ to R⁹ are each independently an alkyl group having 1 to 8 carbon atoms or an aryl group having 6 to 14 carbon atoms, and the R¹⁰ and R¹¹ are each independently a hydrogen atom, an alkyl group having 1 to 8 carbon atoms, or an aryl group having 6 to 14 carbon atoms.

20. The liquid ejection head according to claim 19, wherein the photosensitive resin composition is a single layer.
